(19) United States
(12) Patent Application Publication
(10) Pub. No.: US 2015/0056738 A1
(43) Pub. Date: Feb. 26, 2015

(54) METHOD FOR MANUFACTURING IMAGE SENSOR

(71) Applicant: Joon HWANG, Chungcheongbuk-do (KR)

(72) Inventor: Joon HWANG, Chungcheongbuk-do (KR)

(73) Assignee: DONGBU HITEK CO., LTD., Seoul (KR)

(21) Appl. No.: 14/250,073

(22) Filed: Apr. 10, 2014

(30) Foreign Application Priority Data
Aug. 21, 2013 (KR) 10-2013-0098882

(51) Int. Cl. H01L 27/146

(52) U.S. Cl. CPC H01L 27/14685
USPC 438/65

(57) ABSTRACT

A method of manufacturing an image sensor is provided. The method includes forming a photodiode in a pixel area in a first substrate and forming an insulating layer and a metal wire; forming a color filter layer and a microlens on the insulating layer; attaching a cover glass for the microlens to the insulating layer; back-grinding the first substrate to decrease its thickness; forming a via in the first substrate electrically coupled to the metal wire; forming a first microbump on the via; and forming a second microbump on a logic area of a second substrate; and coupling the first and the second microbumps to electrically couple the pixel area to the logic area.

### CROSS-REFERENCE TO RELATED APPLICATIONS

This application claims under 35 U.S.C. §119 to Korean Patent Application No. 10-2013-0098882, filed Aug. 21, 2013, which is hereby incorporated by reference.

### BACKGROUND

The present disclosure relates to an image sensor and more particularly, to a method of manufacturing an image sensor that may enhance an optical characteristic of a pixel when a bottom emission process is not used.

In general, an image sensor is a semiconductor device that converts an optical image into an electrical signal. Image sensors include a charge coupled device (CCD), which is a device where individual metal-oxide-silicon (MOS) capacitors are very close to one another and charge carriers are stored therein and transferred, and a CMOS image sensor, which is a device employing a switching technique using at least as many MOS transistors as the number of pixels, and that includes a control circuit and a signal processing circuit as peripheral circuits. CMOS image sensors sequentially provide and detect pixel outputs using the transistors, which are formed using CMOS processing.

A unit pixel of a typical CMOS image sensor includes one photodiode PD and four NMOS transistors: a transfer transistor (e.g., labeled Tx) for transferring photo-generated charges from the photodiode PD to a floating diffusion area, a reset transistor (e.g., labeled Rx) for resetting the floating diffusion area (e.g., labeled FD) by setting the potential of a node to a desired value and discharging charges (e.g., labeled Cpd), a drive transistor (e.g., labeled Dx) that functions as a source follower-buffer amplifier, and a select transistor (e.g., labeled Sx) enabling addressing of the pixel using switching.

In this example, the transfer transistor Tx and the reset transistor Rx use native NMOS transistors, the drive transistor Dx and the select transistor Sx use normal NMOS transistors, and the reset transistor Rx is a transistor for correlated double sampling (CDS).

The unit pixel of the CMOS image sensor as described above senses visible-band light from the photodiode area PD using the native transistor, then transfers sensed photo-generated charges to the floating diffusion area FD (namely, to the gate of the drive transistor Dx), and outputs an amount of or proportional to the transferred charges as an electrical signal at an output (e.g., labeled Vout).

FIG. 1 shows a structure of a typical bottom-emission image sensor.

A pixel 22 is formed on and/or in a silicon substrate 21. Metal interconnections or layers M1 to M3 may be on one side of the pixel, a photodiode may be in the pixel, and light enters the silicon substrate 21 at the side or surface opposite from the metal interconnections or layers M1 to M3.

The bottom emission structure of FIG. 1 reduces or prevents loss of light as the light passes through a dielectric, and enables metal interconnections to be formed on or over the photodiode, the area of the pixel may increase, and thus, the characteristic(s) of the image sensor may be enhanced.

When manufacturing the image sensor having such a structure, the rear surface of the silicon substrate 21 (e.g., the surface through which light passes) needs to be thinned.

However, in order to process the rear surface of the silicon substrate 21 to a thickness of 10 μm to 20 μm, there are very complex processes of attaching a wafer or a glass to the front surface of the silicon substrate 21, then grinding the rear surface of the silicon substrate 21, and then thinning the rear surface of the silicon substrate 21 or wafer through a chemical etch.

Also, in order to couple a lead for manufacturing a packaged image sensor, a super-contact process 23 that couples a metal interconnection to the rear surface of the silicon substrate 21 may be needed.

Such a bottom emission CMOS image sensor needs several processes that are very complex, and when grinding and chemical etch are performed, it is difficult to obtain a wafer having a desired and/or uniform thickness and/or rear surface properties (e.g., roughness). Thus, there are one or more limitations in implementing a bottom emission image sensor and/or method of making the same.

### SUMMARY

Embodiments provide a method of manufacturing an image sensor that may enhance one or more optical characteristics of a pixel in an image sensor without using a bottom emission structure.

In one or more embodiments, a method of manufacturing an image sensor includes forming a photodiode in a pixel area of a first substrate and forming an insulating layer and a metal wire (e.g., in the pixel area); forming a color filter layer and a microlens on the insulating layer (e.g., in the pixel area); attaching a cover glass over the microlens to the insulating layer; back-grinding the first substrate to decrease a thickness of the first substrate; forming a via in the first substrate electrically coupled to the metal wire (e.g., in or on the insulating layer); forming a first microbump on the via; forming a second microbump on a logic area of a second substrate; and coupling the first and second microbumps to electrically couple the pixel area to the logic area.

By the method of manufacturing the image sensor according to the proposed embodiment(s), there is no need to manufacture an image sensor according to a typical bottom emission technique, and in the back-grinding process for decreasing the thickness of the first (e.g., pixel) substrate, problems arising from shock(s) applied to the microlenses do not occur.

Also, since it is possible to form microbumps densely enough to electrically couple the logic area to each pixel, it is possible to more stably transmit signals from the pixels to the logic area.

### BRIEF DESCRIPTION OF THE DRAWINGS

FIG. 1 shows a structure of a typical bottom-emission image sensor.

FIGS. 2 to 7 depict structures formed during a method of manufacturing an image sensor according to the present embodiments.

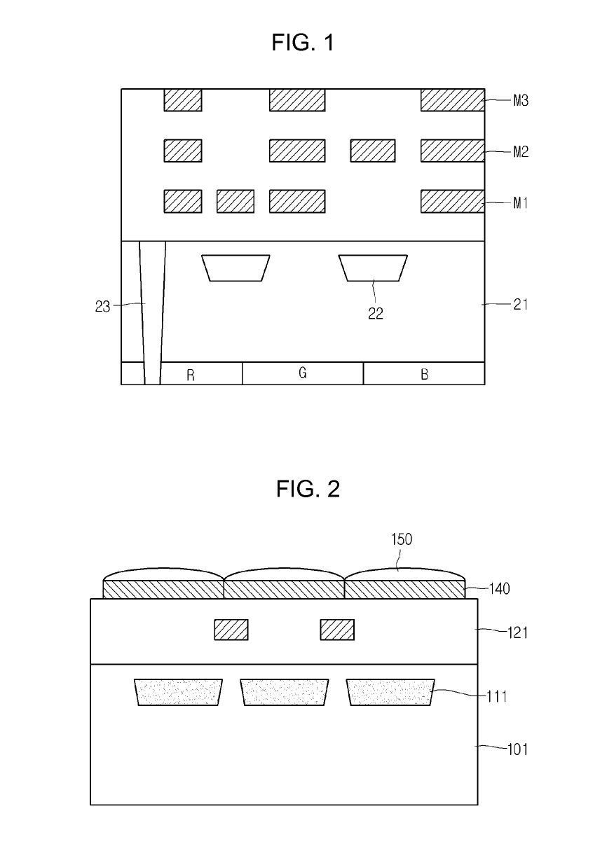

### DETAILED DESCRIPTION OF THE EMBODIMENTS

FIGS. 2 to 7 depict a method of manufacturing an image sensor according to the present embodiments.

In the present embodiments, a pixel area and a logic area are separately manufactured as separate wafers, and the pixel area and the logic area are integrated using a microbump process.

Firstly, referring to FIG. 2, a photodiode 111 corresponding to a given pixel is formed in a first (e.g., pixel area) silicon substrate 101 and a dielectric 121 (e.g., one or more interlayer dielectrics, each of which may comprise a plurality of dielectric sublayers, such as silicon nitride, silicon dioxide [e.g., from tetraethyl orthosilicate (TEOS) or silane], and/or boron- and/or phosphorous-doped silicon dioxide) and a metal interconnection (or metal interconnection layer) 131 are formed on the substrate 101. The dielectric 121 may be a multi-layer structure, as described above. The metal interconnection 131 in the dielectric 121 may also have a multi-layer structure, and metal interconnections 131 may be respectively arranged or patterned in spaces between photodiode areas 111 in order to decrease loss of received light.

In addition, a color filter layer 140 configured to receive light, and pass light of a predetermined wavelength range, band, and/or color through, is formed on the dielectric 121, and a microlens 150 (or an array of such microlenses) is formed on the color filter layer 140. As is known, color filters in the color filter layer correspond to the photodiodes 111, and each color filter transmits only a specific color or wavelength band, and blocks other colors or wavelengths. In addition, the microlenses 150 focus and transfer light onto each photodiode 111. The microlenses 150 may have a curved, dome-like or hemispherical shape, and each microlens 150 may correspond to a unique color filter in the color filter layer 140. Also, a planarization layer may be formed on the color filter layer 140, prior to the microlenses 150. The planarization layer may decrease or remove a height difference between individual color filters when the thickness of the various color filters (e.g., blue, green and red color filters) differs.

A cover glass or other protective covering may be formed on or over the pixel area wafer having such a structure, for a back-grinding process to be performed later.

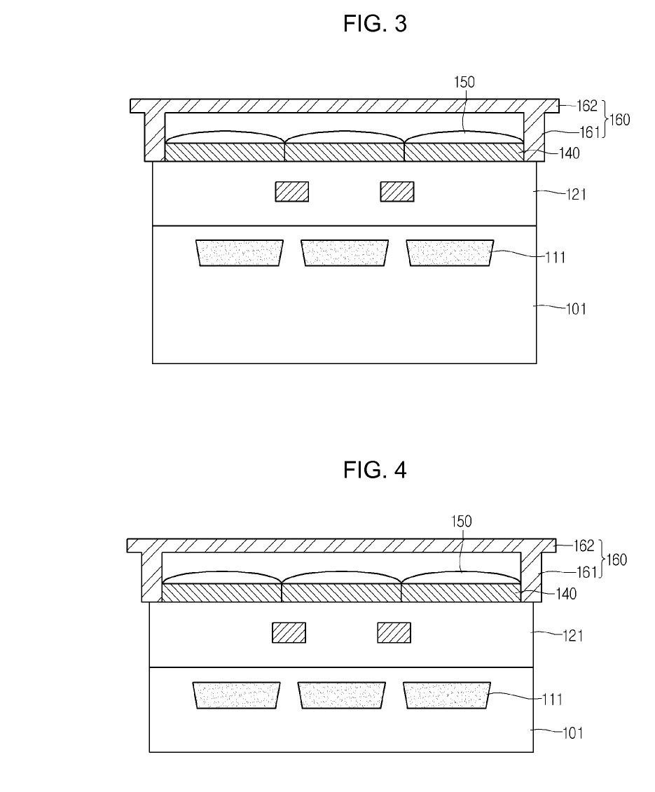

That is, as shown in FIG. 3, after structures for the pixel area such as a photodiode and a color filter are formed on the first wafer or substrate 101, a cover glass 160 is formed over the microlenses 150. The cover glass 160 may comprise a transparent material such as a polycarbonate, a poly(meth)acrylate (e.g., LUCITE), amorphous silicon dioxide or quartz (e.g., that may be a raw material of glass), and includes an upper cover 162 and sidewalls or spacers 161 that enable the upper cover 162 to be a certain distance from the microlenses 150. The sidewalls 161 may be on a portion of the insulating layer 121 that is exposed through the color filter layer 140, and due to the length or height of the sidewalls 161, the upper cover 162 may maintain a certain spacing or distance from the microlenses 150.

The cover glass 160 avoids or eliminates any need to unnecessarily thicken the dielectric 121 in order to support and/or fix a wafer in the back-grinding process.

The cover glass 160 also supports one side of the first wafer or substrate 101 when forming a via hole for electrically coupling the first (e.g., pixel area) wafer 101 to a second (e.g., logic area) wafer, or, as shown in FIG. 4, when grinding a substrate 101 (which may correspond to an epitaxial layer in which the photodiodes 111 are formed).

Referring to FIG. 4, after fixing one side of the first wafer 101 having the cover glass 160 thereon to another fixing unit (not shown), a back-grinding process that decreases the thickness of the rear surface of the first substrate 101 having the photodiodes 111 therein is performed.

In this case, the back-grinding process is performed so that the thickness of the first substrate 101 is within a range of from about 20 μm to 30 μm. The thickness of the first substrate 101 to be achieved or maintained after the back-grinding process takes the following via-hole forming process into account, and thus can be determined in accordance with the depth of the via holes to be formed through the first substrate 101.

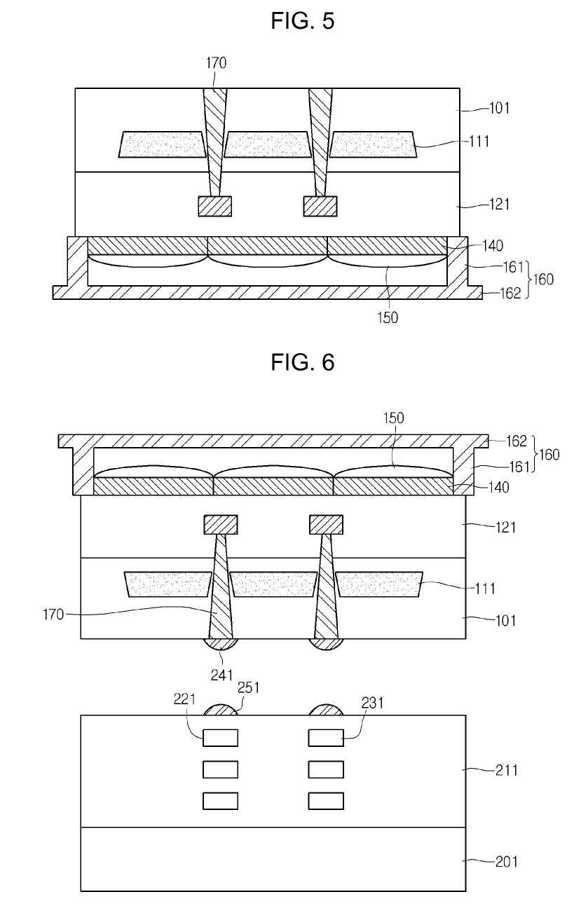

Next, the via-hole forming process for electrically coupling the first (e.g., pixel area) wafer or substrate 101 to the second (e.g., logic area) wafer or substrate 201 is performed, and as shown in FIG. 5, one or more via holes that expose a portion of the metal interconnection 131 (e.g., in each pixel area of the first substrate 101) is formed in the substrate 101.

The first substrate 101 has a first surface (e.g., a top surface) and a second surface (e.g., a bottom surface). The color filter layer 140 and the cover glass 160 are formed on the first surface of the first substrate 101, and the back-grinding process is performed on the second surface of the first substrate 101.

In this case, the via holes pass through the second surface of the first substrate 101, and may expose a portion of the metal interconnection 131 formed in or on the dielectric 121, and a metal material is deposited in the via holes so that a via pattern 170 electrically coupled to the metal interconnection 131 is formed. Any excess metal material deposited outside the via holes may be removed by etchback (e.g., blanket plasma etching) or polishing (e.g., chemical mechanical polishing).

Next, referring to FIG. 6, a second (e.g., logic area) wafer or substrate 201 (i.e., a separate wafer or substrate) is provided. The logic area wafer includes a substrate 201, a dielectric 211 on the substrate 201, and a plurality of metal interconnections 221 and 231 in the dielectric 211. However, the second (e.g., logic area) wafer or substrate 201 merely shows one example of a logic wafer or substrate, and logic area wafers or substrates of various shapes, sizes and/or configurations can be provided.

After forming a via pattern 170 in the first (e.g., pixel area) wafer or substrate 101, a microbump 241 is formed at the end of each via in the via pattern 170, and microbumps 251 corresponding to the microbumps 241 are also formed on the logic area wafer or substrate. In order to prevent confusion, the microbumps 241 formed on the first (e.g., pixel area) substrate are called “first microbumps,” and the microbumps 251 formed on the logic area substrate are called “second microbumps 251.”

The first microbumps 241 are electrically coupled to the via pattern 170 and to the metal interconnection 131 in the dielectric 121. Also, the second microbumps 251 on the logic wafer are electrically coupled to the metal interconnections 221 and 231 in the dielectric 211. Such electrical coupling between the metal interconnections 221 and 231 and the second microbumps 251 on the logic wafer may be implemented using a plurality of vias (not shown) in an uppermost dielectric layer of the dielectric 211. The metal interconnections 221 and 231 on the logic wafer are structurally similar or identical to the metal interconnections 131 on the pixel wafer, although the line width may differ. Also, metal interconnections 221 and 231 on the logic wafer have increasing dimensions from lowermost layer (i.e., closest to the substrate 201) to uppermost layer (i.e., farthest away from the substrate 201), although the chemical composition and/or sublayering within each layer may be the same or similar among the various layers. As with the dielectric 121 on the pixel wafer, the dielectric 211 on the logic wafer may comprise a multi-layer structure (e.g., one or more interlayer dielectrics, each of which may comprise a plurality of dielectric sublayers, such as silicon nitride, silicon dioxide, and/or boron- and/or phosphorous-doped silicon dioxide).

In particular, the microbumps 241 on the first (e.g., pixel area) substrate 101 are formed on a pixel basis (e.g., each microbump 241 corresponds to a unique pixel). Since the microbumps for coupling to the second (e.g., logic area) wafer or substrate may have a density corresponding to a 1:1 microbump:pixel ratio, information on an image obtained by each pixel may be more accurately transferred to the logic area wafer.

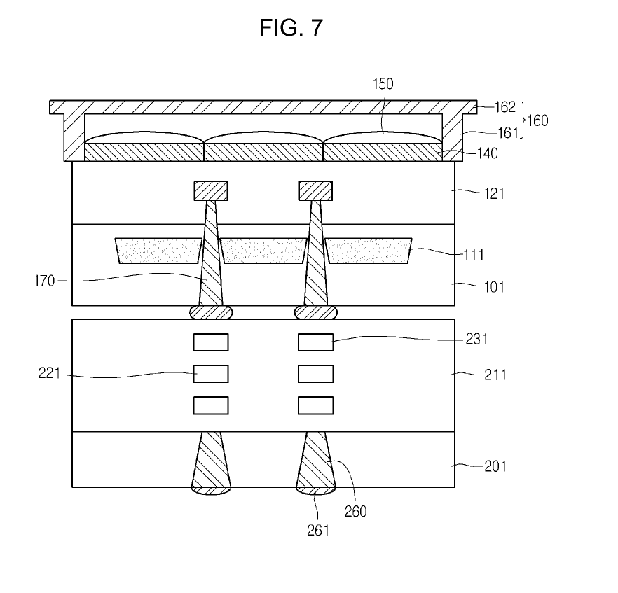

In order to electrically couple the second (e.g., logic area) wafer or substrate 201 to the first (e.g., pixel area) substrate 101, the microbumps 241 and 251 on each substrate are bonded to one another so that the logic in the second (e.g., logic area) substrate 201 and the pixels in the first (e.g., pixel area) wafer substrate 101 are electrically coupled as shown in FIG. 7.

In addition, as shown in FIG. 7, in order to package the substrate(s) including the image sensor, a via pattern (e.g., comprising a plurality of through-vias) electrically coupled to structures in or on the logic area substrate 201 and/or the metal interconnections 221 and 231 formed on the logic area substrate 201 are formed through the logic area substrate 201. That is, one or more via holes are formed in the logic area substrate 201, and metal is deposited in the via holes to form the vias 260 coupled to the structures in or on the logic area substrate 201 and/or the metal interconnections 221 and 231 in the dielectric 211 (e.g., vias or contacts from the lowermost layer of metal interconnections 221 and 231 to the nearest surface of the second substrate 201). Also, one or more bumps 261 for electrically coupling the second substrate 201 to an external chip or circuit board are formed on the vias 260. The logic area and the pixel area may be coupled to the pads of other circuits through the bumps 261 and the via pattern 260 that is formed in the logic area substrate 201.

By the above-described embodiments of the method of manufacturing an image sensor, there is no need to manufacture a bottom emission-type image sensor, and in the back-grinding process for decreasing the thickness of the first (e.g., pixel area) substrate, problems do not arise due to shock to the microlenses.

Also, since it is possible to form microbumps electrically coupled to the logic area in a density allowing each pixel to be separately coupled or bonded, it is possible to more stably transmit a signal from each pixel.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other embodiments.

What is claimed is:

1. A method of manufacturing an image sensor, the method comprising:
forming a photodiode in a pixel area of a first substrate and forming a dielectric and a metal interconnection;
forming a color filter layer and a microlens on the dielectric;
attaching a cover glass over the microlens;
back-grinding the first substrate to decrease a thickness of the first substrate;
forming a via in the first substrate electrically coupled to the metal interconnection;
forming a first microbump on the via; and
forming a second microbump on a logic area of a second substrate; and
coupling the first and second microbumps to electrically couple the pixel area to the logic area.

2. The method according to claim 1, wherein the first microbump corresponds to a color filter in the color filter layer.

3. The method according to claim 1, comprising forming a plurality of photodiode areas in a corresponding plurality of pixels in the first substrate.

4. The method according to claim 3, comprising forming a corresponding via and a corresponding first microbump in each of the pixels.

5. The method according to claim 1, wherein back-grinding is performed on the first substrate while the first substrate is supported by the cover glass.

6. The method of claim 1, wherein the cover glass includes a sidewall on the dielectric and an upper cover on the sidewall a certain or predetermined distance from the microlens.

7. The method according to claim 6, wherein the sidewalls or spacers contact the dielectric.

8. The method according to claim 6, wherein the cover glass comprises quartz.

9. The method according to claim 1, wherein, after back-grinding, the thickness of the first substrate is within a range of 20 μm to 30 μm, inclusive.

10. The method according to claim 1, comprising forming a plurality of photodiodes in the first substrate.

11. The method according to claim 1, wherein the dielectric on the first substrate comprises a plurality of dielectric layers, and the metal interconnection on the first substrate comprises a plurality of metal interconnections.

12. The method according to claim 11, comprising forming a plurality of vias in the first substrate, each via electrically coupled to one of the metal interconnections.

13. The method according to claim 12, comprising forming a unique first microbump on each of the plurality of vias in the first substrate.

14. The method according to claim 13, comprising forming a plurality of second microbumps on the second substrate.

15. The method according to claim 14, wherein the first and second microbumps are present in a 1:1 ratio.

16. The method according to claim 1, wherein the color filter layer comprises a plurality of color filters, each having one of a plurality of colors, and the method comprises forming a plurality of microlenses on the color filters.

17. The method according to claim 14, wherein the second substrate comprises a second plurality of dielectric layers and a second plurality of metal interconnections.

18. The method according to claim 17, wherein the second plurality of metal interconnections comprise a plurality of different metal layers.

19. The method according to claim 17, wherein each of the plurality of second microbumps is electrically coupled to a unique one of the second plurality of metal interconnections or to a unique structure in or on the second substrate.
